(19) United States
(12) Patent Application Publication
(10) Pub. No.: US 2021/0305152 A1
(43) Pub. Date: Sep. 30, 2021

(54) INVERTED, SELF-ALIGNED TOP-VIA STRUCTURES

(71) Applicant: INTERNATIONAL BUSINESS MACHINES CORPORATION, Armonk, NY (US)

(72) Inventors: DANIEL JAMES DECHENE, Watervliet, NY (US); Craig Michael Child, Gansevoort, NY (US); Lawrence A. Clevenger, Saratoga Springs, NY (US); Kisik Choi, Watervliet, NY (US); Brent Anderson, Jericho, VT (US)

(21) Appl. No.: 16/830,550

(22) Filed: Mar. 26, 2020

(51) Int. Cl. H01L 23/522; H01L 21/768; H01L 23/532; H01L 23/528

(52) U.S. Cl. CPC H01L 23/5226; H01L 21/76897; H01L 21/76877; H01L 23/5283; H01L 21/76804; H01L 23/53209

(57) ABSTRACT

A multilayered integrated circuit includes a first layer with a first conductive element overlaying a substrate, a second layer with a second conductive element overlaying the first layer, an intermediate layer between the first layer and the second layer, and a via structure. The via structure is partially embedded within the intermediate layer and is communicatively coupled to the first conductive element and the second conductive element. The via structure extends from the first conductive element and has a first end with a first end width and a second end with a second end width. The second end is further from the substrate than the first end and the first end width is greater than the second end width such that the via structure tapers between the first end and the second end of the via structure.

### BACKGROUND

The present invention generally relates to multilayered integrated circuits (ICs) and methods of fabricating multilayered ICs. More specifically, the present invention relates to fabrication methods and related multilayered ICs having interconnects with tapered, inverted metal-filled via structures.

ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. Layers of interconnection structures are formed above these logical and functional layers during the BEOL stage to complete the IC.

Most ICs need more than one layer of wires/lines to form all of the necessary connections, and as many as 5-12 layers are added in the BEOL process. The various interconnect structures in the BEOL layers can include the above-described interconnect lines/wires, as well as metal-filled interconnect via structures configured to couple one line/wire to another and/or couple one wafer layer to another. The conductive material used in the lines/wires/via structures can include, for example, copper or a copper alloy. Within an IC metallization layer, metal-filled via structures run substantially normal to the semiconductor substrate, and metal lines run substantially parallel to the semiconductor substrate. The signal speed can be enhanced, and “crosstalk” between signals in adjacent lines can be reduced, by embedding the interconnect structures (i.e., metal lines and metal-filled via trenches) within a low-k dielectric material.

### SUMMARY

Embodiments of the present invention are directed to a multilayered integrated circuit (IC). The multilayered IC includes a first layer with a first conductive element overlaying a substrate, a second layer with a second conductive element overlaying the first layer, an intermediate layer between the first layer and the second layer, and a via structure. The via structure is partially embedded within the intermediate layer and is communicatively coupled to the first conductive element and the second conductive element. The via structure has a first end with a first end width and a second end with a second end width, the second end further from the substrate than the first end, and the first end width greater than the second end width such that the via structure tapers between the first end and the second end of the via structure.

Another non-limiting example of the multilayered IC includes a first layer with a first conductive element overlaying a substrate, a second layer with a second conductive element overlaying the first layer, an intermediate layer between the first layer and the second layer, and a via structure. The via structure is partially embedded within the intermediate layer, is communicatively coupled to the first conductive element and the second conductive element, has a first end with a first end width, a second end with a second end width, the second end further from the substrate than the first end, and the first end width greater than the second end width such that the via structure tapers between the first end and the second end of via structure. The second conductive element defines a recess, the second end of the via structure is contained within the recess, and both the via structure and the first conductive element are formed from a thick first layer.

Embodiments of the present invention are also directed to a method of fabricating a multilayered IC. A non-limiting example of the method includes depositing a first layer on a substrate. A via structure is defined extending from the first layer, the via structure having a first end and a second end, the first end extending from the first conductive element and having a first end width, the second end further from the substrate than the first end and having a second end width, the first end width greater than the second end width such that the via structure tapers between the first end and the second end of the via structure. A first conductive element is defined from the first layer such that the via structure communicatively coupled to the first conductive element, an intermediate layer deposited on the first conductive element and the via structure such that the via structure is embedded within the intermediate layer, a second layer deposited on the intermediate layer and the via structure, and a second conductive element defined in the second layer such that the via structure is communicatively coupled to the second conductive element.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1-13 depict cross-sectional views of a portion of a multilayer IC illustrating the results of fabrication operations according to embodiments of the present invention, in which:

FIG. 1 depicts a cross-sectional side view of the multilayer IC after fabrication operations to deposit a first layer on a substrate;

FIG. 2 depicts a cross-sectional side view of the multilayer IC subsequent to coating the first layer with resist for patterning a via pillar;

FIG. 3 depicts a cross-sectional side view of the multilayer IC subsequent to patterning the via pillar in the resist coating overlaying the first layer;

FIG. 4 depicts a cross-sectional view of the multilayer IC subsequent to etching the first layer and defining a via structure with tapered sidewalls in the first layer;

FIG. 5 depicts a cross-sectional view of the multilayer IC subsequent to coating the via structure and the first layer with a resist coating for pattering the first layer;

FIG. 6 depicts a cross-sectional view of the multilayer IC subsequent to patterning the resist coating overlaying the via structure and the first layer;

FIG. 7 depicts a cross-sectional view of the multilayer IC subsequent to defining a first conductive element from the first layer;

FIG. 8 depicts a cross-sectional view of the multilayer IC subsequent to depositing an interface material over the first conductive element and the via structure;

FIG. 9 depicts a cross-sectional view of the multilayer IC subsequent to depositing an intermediate layer on the first conductive element and the via structure;

FIG. 10 depicts a cross-sectional view of the multilayer IC subsequent to polishing the intermediate layer such that a second end of the via structure protrudes from a surface of the intermediate layer;

FIG. 11 depicts a cross-sectional view of the multilayer IC subsequent to depositing a second layer on the second end of the via structure and on the surface of the intermediate layer;

FIG. 12 depicts a cross-sectional view of the multilayer IC subsequent to defining a second conductive element from the second layer; and

FIG. 13 depicts another example of a multilayer IC showing electrical connectivity between the second conductive element and the second end of the via structure at a corner of the registration process window.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with three-digit reference numbers.

### DETAILED DESCRIPTION

For the sake of brevity, conventional techniques related to multilayered integrated circuit (IC) and multilayered IC fabrication may or may not be described in detail herein. Moreover, the various tasks and process steps described herein can be incorporated into a more comprehensive procedure or process having additional steps or functionality not described in detail herein. In particular, various steps in the manufacture of multilayered ICs and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, in contemporary semiconductor IC fabrication processes, a large number of multilayered ICs and conductive interconnect layers are fabricated on each IC/chip. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically is not enough room on the chip surface to create all of the necessary connections in a single layer, chip manufacturers build vertical levels of interconnects. While simpler ICs can have just a few metallization layers, complex ICs can have ten or more layers of wiring.

BEOL-stage interconnect structures that are physically close to FEOL-stage components (e.g., transistors and the like) need to be small because they attach/join to the components that are themselves very small and often closely packed together. These lower-level lines, which can be referred to as local interconnects, are usually thin and short in length. Global interconnects are higher up in the IC layer structure and travel between different blocks of the circuit. Thus, global interconnects are typically thick, long, and more widely separated local interconnects. Vertical connections between interconnect levels (or layers), called metal-filled via structures, allow signals and power to be transmitted from one layer to the next. For example, a through-silicon via (TSV) structure is a conductive contact that passes completely through a given semiconductor wafer or die. In multi-layer IC configurations, for example, a TSV structure can be used to form vertical interconnections between a multilayered IC located on one layer/level of the multilayer IC and an interconnect layer located on another layer/level of the IC. These vertical interconnect structures include an appropriate metal and provide the electrical connection of the various stacked metallization layers.

Insulating dielectric materials are used throughout the layers of an IC to perform a variety of functions including stabilizing the IC structure and providing electrical isolation of the IC elements. Additionally, in order to provide a parasitic resistance and capacitance (RC) level that is sufficiently low to support high signal speed applications, regions of the BEOL dielectric material can be formed from low-k and/or ultra-low-k (ULK) dielectric materials having a dielectric constant of less than silicon dioxide, and the interconnect structures (e.g., wire lines and metal-filled via trenches) can be formed from copper-containing material.

However, there are difficulties with integrating low-k/ULK dielectric materials with metal interconnects in the insulating dielectric layers of a multilayer IC. For example, it is a challenge to align via structures with conductive elements in metal layers using known fabrication operations and known interconnect structures. In applications where a cross-sectional width dimension of the via structure is close to the cross-sectional width dimension of the line/wire, misalignment between the via structures and the metal lines/wires can reduce the surface area of the actual line/via structure interface and leave uncoupled the corners of the misaligned line/via structure that should interface to the opposing line/via structure. Metal line/via structure misalignments that reduce the expected (e.g., nominal) metal line/via structure interface surface result in undesirable resistance variability, which negatively impacts IC performance, particularly for high speed applications.

Turning now to an overview of the aspects of the invention, one or more embodiments of the invention address the above-described shortcomings of the prior art by providing processes and resulting structures that include defining a via structure with a second end protruding from an intermediate layer opposite a first layer and extending from a first conductive structure in the first layer. The protruding second end of the via structure forms an interface between the via structure and a subsequently defined second conductive element (e.g., a metal wire) of a second layer, the via structure thereby providing electrical communication between the first conductive structure in the first layer with the second conductive structure in the second layer. The resulting interface between the via structure and the second conductive structure in the second layer provides the interconnect structure with favorable resistance/capacitance (R/C) characteristics, including at the corners of the registration process window.

In accordance with aspects of the invention, the via structures are arranged substantially normal to conductive elements (e.g., metal lines) in an interconnect structure. A protruding second end of the via structure is defined on the via structure at an end opposite the first layer such that the via structure extends into the second conductive element of the second layer can increase the interfacial area between the via structure and the second conductive structure in the second layer, thereby improving the R/C characteristics of the interconnect structure. The protruding second end of the via structure opposite the first layer can be formed, for example, by a polishing operation and/or an etching operation that preferentially removes dielectric material over via structure material. The resulting protruding second end of the via structure allows the subsequently defined second conductive structures in the second layer to self-align to the via structure protrusion, with a recess defined in the second conductive structure, increasing electrical contact area between the protruding second end of the via structure and the overlaying second conductive element, reducing electrical resistance and providing favorable R/C characteristics when the multilayered IC is constructed at edges of the registration process window. It is contemplated that the via structure can be inverted (or tapered), i.e., having a first end with a first end width, a second end with a second end, the second end further from the substrate than the first end, and the first end width greater than the second end width such that the via structure tapers between the first end and the second end of the via structure.

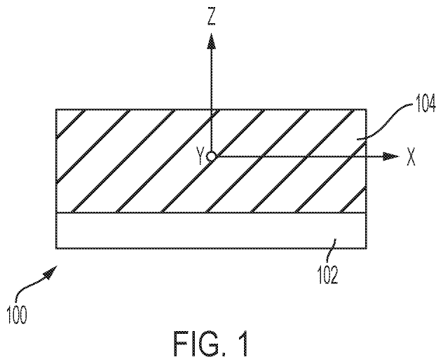

Turning now to a more detailed description of aspects of the present invention, FIGS. 1-13 depict cross-sectional views of a portion of a multilayered IC 100 after the application thereto of various fabrication processes according to embodiments of the present invention. The portion of the multilayered IC 100 illustrated in FIG. 1 is a metallization layer of the multilayered IC 100 where various interconnect structures (e.g., metal lines/wire and metal-filled via trenches that form via structures) will be formed in a dielectric material. Although FIGS. 1-13 depict two-dimensional cross-sectional views of the multilayered IC 100, it is understood that the multilayered IC 100 and the structures depicted therein extend in three dimensions. More specifically, the multilayered IC 100 and the structures formed therein extend along a first axis (X-axis) to define a length, a second axis (Y-axis) perpendicular the first axis to define a width, and a third axis (Z-axis) perpendicular to the first and second axes to define a height (i.e., vertical thickness). Although not depicted, persons skilled in the relevant arts will understand that the multilayered IC 100 and the structures formed therein, e.g., via structures and conductive elements, extend in the Z-axis direction in accordance with a pattern created for the specific circuit designs and applications of the multilayered IC 100.

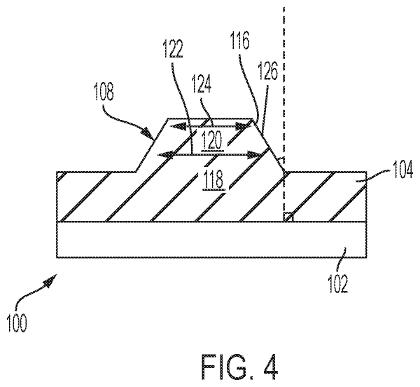

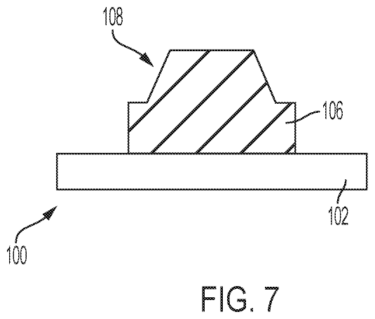

Referring now to FIG. 1, known fabrication operations have been used to form the multilayered IC 100 including a substrate 102 and a first layer 104. In some examples of the present invention the first layer 104 is a thick first layer, e.g., having a height selected that is equal to or greater than a combined height of a first conductive element 106 (shown in FIG. 7) and a via structure 108 (shown in FIG. 4) formed from the first layer 104 for forming both the first conductive element 106 and the via structure 108 from the first layer 104. The substrate 102 includes middle-of-line (MOL) and front-end-of-line (FEOL) structures (not shown separately) formed in MOL and FEOL regions (not shown separately) of the substrate 102. The layers above the substrate 102 form a BEOL region of the multilayered IC 100. Any number of layers can be included in the BEOL region of the multilayered IC 100.

The substrate 102 can include a semiconducting material, a conducting material, an insulating material, or any combination thereof. When the substrate 102 includes a semiconducting material, any material having semiconductor properties such as, for example, Si, SiGe, SiGeC, SiC, Ge alloys, GaAs, InAs, InP and other III/V or II/VI compound semiconductors, can be used. The substrate 102 can be a layered semiconductor such as, for example, Si/SiGe, Si/SiC, silicon-on-insulators (SOIs) or silicon germanium-on-insulators (SGOIs). When the substrate 102 includes an insulating material, the insulating material can be an organic insulator, an inorganic insulator or a combination thereof, including multilayers. When the substrate 102 includes a conducting material, the substrate 102 can include, for example, polysilicon, an elemental metal, alloys of elemental metals, a metal silicide, a metal nitride or any combination thereof, including multilayers. When the substrate 102 includes a semiconducting material, one or more multilayered ICs such as, for example, complementary metal oxide semiconductor (CMOS) devices can be fabricated in FEOL regions thereof. When the substrate 102 includes a combination of an insulating material and a conductive material, regions of the substrate 102 can be one or more of the previously described BEOL layers having multilayered interconnect structures embedded therein.

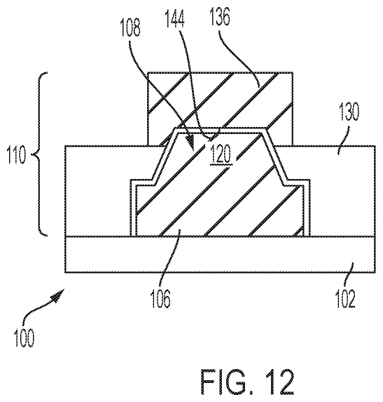

The conductive material forming the first layer 104 is deposited by a deposition process, including, by not limited to, chemical vapor deposition (CVD), plasma enhanced chemical vapor deposition (PECVD), sputtering, chemical solution deposition or plating that fills from the bottom upwards (e.g., a bottom-up plating process). The first layer 104 can include, for example, polysilicon, SiGe, a conductive metal, an alloy including at least one conductive metal, a conductive metal silicide or combinations thereof. The conductive material can be a conductive metal, such as copper (Cu), tungsten (W), aluminum (Al), cobalt (Co), ruthenium (Ru), rhodium (Rh), platinum (Pt), or any combination thereof. In one or more embodiments of the present invention, the conductive material of the first layer 104 includes Cu or a Cu alloy. In subsequent fabrication operations, the first layer 104 will be used to form a first conductive element 106 (shown in FIG. 7) and a via structure 108 (shown in FIG. 4) of an interconnect structure 110 (shown in FIG. 12) on the substrate 102.

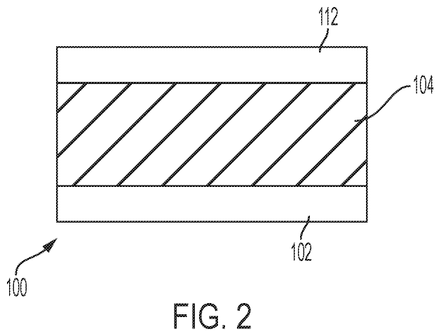

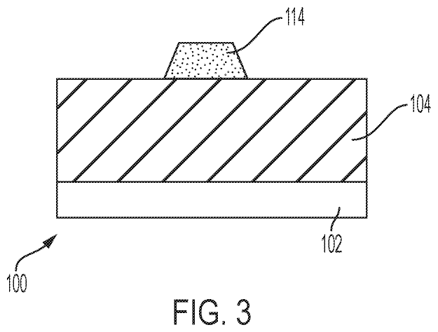

FIGS. 2-4 show operations for defining the via structure 108. Specifically, FIG. 2 depicts a cross-sectional side view of the multilayered IC 100, subsequent to depositing a resist, resist stack or hardmask coating 112 on the first layer 104 for patterning a resist, resist stack, or hardmask pillar 114 (shown in FIG. 3) from the resist, resist stack, or hardmask coating 112. FIG. 3 depicts a cross-sectional side view of the multilayered IC 100 subsequent to operations to pattern the resist, resist stack or hardmask coating 112 (shown in FIG. 2) to form the resist, resist stack, or hardmask pillar 114 (shown in FIG. 3) and expose portions of the first layer 104 for an etching operation. FIG. 4 depicts a cross-sectional side view of the multilayered IC 100 subsequent to etching the first layer 104 to define the via structure 108 and removal of the resist, resist stack, or hardmask pillar 114 (shown in FIG. 3).

It is contemplated that via structure 108 have a first end 118, a second end 120, and sidewalls 116. The first end 118 extends from the first conductive element 106 (shown in FIG. 7), the second end 120 is further from the substrate 102 than the first end 118, and the etching process defines sidewalls 116 bounding the via structure 108 taper between the first end 118 and the second end 120. More specifically, the via structure 108 is inverted, i.e., tapers such that a first end width 122 of the first end 118 is greater than (i.e. wider) than a second end width 124 of the second end 120 of the via structure 108. The etching technique used to define the taper can employ buffered hydrofluoric acid (BHF), hydrofluoric acid (HF), hydrofluoric nitric acid (HNA), phosphoric acid, HF diluted by ethylene glycol (HFEG), hot ammonia, tetramethylammonium hydroxide (TMAH), hydrochloric acid (HC1), or any combination thereof.

It is also contemplated that the sidewalls 116 of the via structure 108 define a taper angle 126. More specifically, the sidewalls 116 of the via structure 108 define the taper angle 126 relative to a line that is substantially orthogonal relative to the substrate 102 to define a predetermined (e.g., desired) taper angle 126. In some embodiments of the present invention, the taper angle 126 is between about 1 degree and about 10 degrees. Preferably, the taper angle 126 is between about 1 degree and about 7 degrees. More preferably, the taper angle 126 is between about 2 degrees and about 5 degrees. In accordance with certain embodiments of the invention, the taper angle 126 of the sidewalls 116 is defined using an anisotropic etching technique. Taper angles within these ranges increase interface area between the second end 120 of the via structure 108 and a second conductive element 136 (shown in FIG. 12) of the interconnect structure 108, improving R/C performance throughout the process window for forming the second conductive element 136.

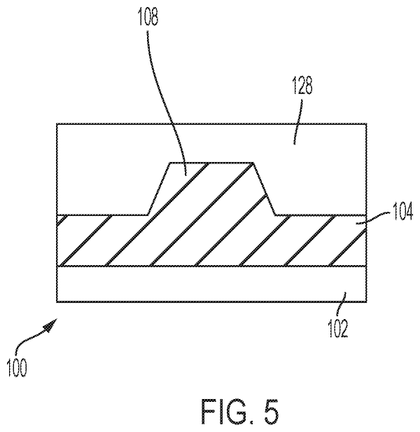

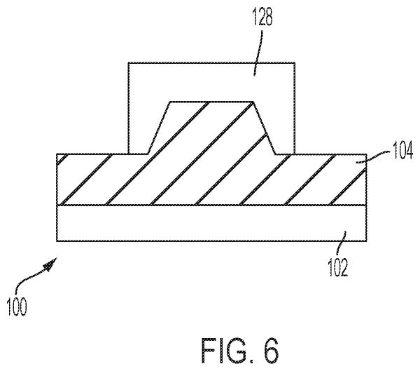

FIGS. 5-7 show operations for forming the first conductive element 106 (shown in FIG. 7). FIG. 5 depicts a cross-sectional view of the multilayered IC 100 subsequent to depositing a resist, resist stack, or hardmask 128 on the first layer 104. FIG. 6 depicts a cross-sectional view of the multilayered IC 100 subsequent to patterning the resist, resist stack, or hardmask 128 deposited on the first layer 104. FIG. 7 depicts a cross-sectional view of the multilayered IC 100 subsequent to defining a first conductive element 106 from the first layer 104 and in electrical communication with the via structure 108.

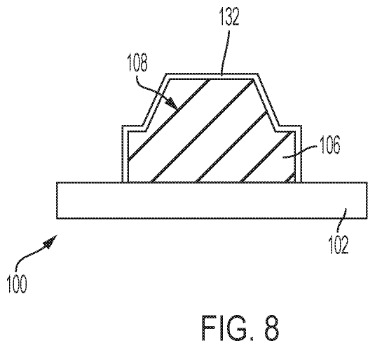

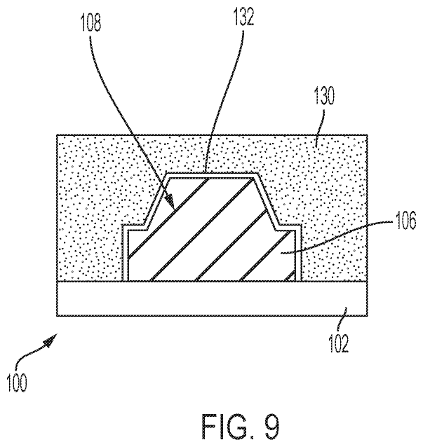

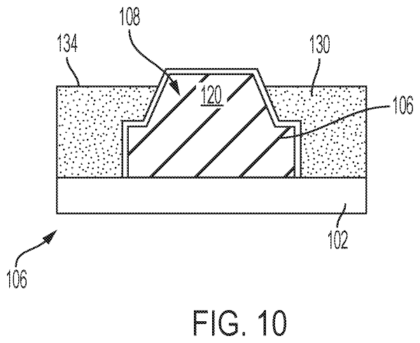

FIGS. 8-10 show operations for forming an intermediate layer 130 (shown in FIG. 9). FIG. 8 depicts a cross-sectional view of the multilayered IC 100 subsequent to depositing an interface material 132 over the first conductive element 106 and the via structure 108. Example materials of the interface material 132 can include TaN, TiN, etc. FIG. 9 depicts a cross-sectional view of the multilayered IC 100 subsequent to depositing the intermediate layer 130 over the first conductive element 106 and the via structure 108. FIG. 10 depicts a cross-sectional view of the multilayered IC 100 subsequent to polishing the intermediate layer 130 such that the second end 120 of the via structure 108 protrudes from a surface 134 of the intermediate layer 130, the via structure 108 embedded in the intermediate layer 130, the via structure 108 and the first conductive element 106 having a height that is greater than a thickness of the intermediate layer 130.

In some embodiments of the invention, the intermediate layer 130 includes an inter-level dielectric (ILD), such as an inorganic dielectric or organic dielectric. The ILD is deposited by a deposition process, including, but not limited to CVD, PVD, plasma enhanced CVD, atomic layer deposition (ALD), evaporation, chemical solution deposition, or like processes. Non-limiting examples of ILD materials include SiO₂, silsesquioxanes, carbon-doped oxides (i.e., organosilicates) that include atoms of Si, C, 0 and H, thermosetting polyarylene ethers, or multilayers thereof. The ILD can be a low-k or ultra-low-k dielectric material with a dielectric constant that is about 4.0 or less, or a dielectric constant of about 2.8 or less.

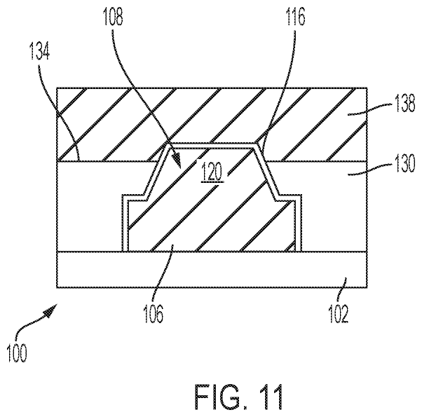

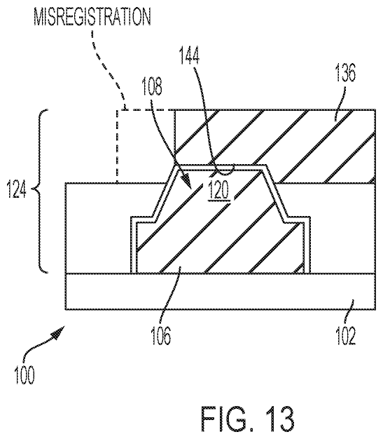

FIGS. 11-13 show operations for forming a second conductive element 136 (shown in FIG. 12) of the interconnect structure 110 (shown in FIG. 12). FIG. 11 depicts a cross-sectional view of the multilayered IC 100 subsequent to depositing a second layer 138 on the second end 120 of the via structure 108 and on the surface 134 of the intermediate layer 130. FIG. 12 depicts a cross-sectional view of the multilayered IC 100 subsequent to defining the second conductive element 136 from the second layer 138. FIG. 13 depicts another example of a multilayered IC 100 showing electrical connectivity between the second conductive element 136 and the second end 120 of the via structure 108 at a corner of the registration process window employed for defining the second conductive element 136 in the second layer 138.

In some embodiments of the invention the second layer 138 can include, for example, polysilicon, SiGe, a conductive metal, an alloy including at least one conductive metal, a conductive metal silicide or combinations thereof. The conductive material can be a conductive metal, such as copper (Cu), tungsten (W), aluminum (Al), cobalt (Co), ruthenium (Ru), rhodium (Rh), platinum (Pt), or any combination thereof. In one or more embodiments of the present invention the conductive material of the second layer 138 includes Cu or a Cu alloy. The second layer 138 can be deposited by a deposition process, including, by not limited to, chemical vapor deposition (CVD), plasma enhanced chemical vapor deposition (PECVD), sputtering, chemical solution deposition or plating that fills from the bottom upwards (e.g., a bottom-up plating process).

Notably, the second end 120 of the via structure 108 extends into the second layer 138 such that a portion of the sidewall 116 is contained within the second layer 138, e.g., surrounding on three sides. In some embodiments of the invention, the second layer 138 completely surrounds the second end 120 of the via structure 108. Surrounding the second end 120 of the via structure 108 with the second conductive element 136 improves R/C characteristics of the interconnect structure 110 by forcing self-alignment of the second conductive element 136 to the via structure 108. Specifically, as the via structure 108 protrudes from the surface 134 of the intermediate layer 130, the second conductive element 136 wraps about the second end 120 of the via structure 108. More specifically, the second conductive element 136 is formed with a recess 144 (shown in FIG. 12) containing the second end 120 of the via structure 108.

As shown in FIG. 13, the wraparound arrangement of the second conductive element 136 such that the second end 120 of the via structure 108 is contained within the recess 144 of the second conductive element 136 renders the interconnect structure 108 less susceptible to both overlay error (registration variation) and linewidth variation due the arrangement of the second end 120 of the via structure 108 within the recess 144 when the second conductive element 136 is defined in misregistration to the via structure 108. The reduced susceptibility to overlay error and linewidth error translates into closer to nominal R/C characteristics when forming the interconnect structure 110 at the corners of the process window for formation of the via structure 108 and/or the second conductive element 136. Closer to nominal R/C characteristics at corners of the process window in turn can improve system-level performance of the interconnect structure 110, reducing the margin otherwise necessary to be built into the design to accommodate R/C characteristics at the corners of the process window.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

As previously noted herein, for the sake of brevity, conventional techniques related to multilayered IC and integrated circuit (IC) fabrication may or may not be described in detail herein. By way of background, however, a more general description of the multilayered IC fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a multilayered IC according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

1. A multilayered integrated circuit (IC) comprising:
a first layer with a first conductive element overlaying a substrate;
a second layer with a second conductive element overlaying the first layer;
an intermediate layer between the first layer and the second layer; and
a via structure partially embedded within the intermediate layer and communicatively coupled to the first conductive element and the second conductive element,
wherein the via structure has a first end extending from the first conductive element and a second end further from the substrate than the first end,
wherein: the first end of the via structure has a wide end width, the second end of the via structure has a narrow end width, and the wide end width is greater than the narrow end width such that the via structure tapers between the first end and the second end of the via structure,
wherein: the second conductive element defines therein a recess, and the narrow end width of the via structure is contained within the recess, a width of the first conductive element being wider than the recess and the narrow end width contained within the recess,
wherein a combined width of the first conductive element and the intermediate layer is configured to be greater that a wide portion of the second conductive element.

2. The multilayered IC of claim 1, wherein the second conductive element defines therein a recess, and wherein the second end of the via structure is contained within the recess.

3. The multilayer IC of claim 1, wherein the via structure tapers at a taper angle between about 1 degree and about 10 degrees.

4. The multilayer IC of claim 1, wherein the via structure tapers at a taper angle between about 1 degree and about 7 degrees.

5. The multilayer IC of claim 1, wherein the via structure tapers at a taper angle between about 2 degrees and about 5 degrees.

6. The multilayered IC of claim 1, wherein the first conductive element is formed from a metal selected from a group consisting of copper, tungsten, cobalt, rhodium, platinum, or combinations thereof.

7. The multilayered IC of claim 1, wherein the second conductive element is formed from a metal selected from a group consisting of copper, tungsten, cobalt, rhodium, platinum, or combinations thereof.

8. The multilayered IC of claim 1, wherein the via structure is formed from a metal selected from a group consisting of copper, tungsten, cobalt, rhodium, platinum, or combinations thereof.

9. The multilayered IC of claim 1, wherein the via structure and the first conductive element are formed from a thick first layer.

10. The multilayered IC of claim 1, wherein the intermediate layer comprises a dielectric material.

11. The multilayer IC of claim 1, wherein the via structure and the first conductive element define a height extending from the substrate that is greater than a thickness of the intermediate layer.

12. A multilayered integrated circuit comprising:
a first layer with a first conductive element overlaying a substrate;
a second layer with a second conductive element overlaying the first layer;
an intermediate layer between the first layer and the second layer; and
a via structure partially embedded within the intermediate layer and communicatively coupled to the first conductive element and the second conductive element,
wherein the via structure has a first end extending from the first conductive element and a second end further from the substrate than the first end,
wherein: the first end of the via structure has a wide end width, the second end of the via structure has a narrow end width, and the wide end width is greater than the narrow end width such that the via structure tapers between the first end and the second end of the via structure,
wherein: the second conductive element defines therein a recess, and the narrow end width of the via structure is contained within the recess, a width of the first conductive element being wider than the recess and the narrow end width contained within the recess,
wherein the via structure and the first conductive element are formed from a thick first layer,
wherein a combined width of the first conductive element and the intermediate layer is configured to be greater that a wide portion of the second conductive element.

13. A method of fabricating a multilayered integrated circuit (IC), the method comprising:
depositing a first layer on a substrate;
defining a via structure from the first layer, the via structure having a first end and a second end, the first end extending from the first conductive element and having a wide end width, the second end further from the substrate than the first end and having a narrow end width, the wide end width greater than the narrow end width such that the via structure tapers between the first end and the second end of the via structure;
defining a first conductive element from the first layer, the via structure communicatively coupled to the first conductive element;
depositing an intermediate layer on the first conductive element and the via structure such that the via structure is embedded in the intermediate layer;
depositing a second layer on the intermediate layer and the via structure; and
defining a second conductive element in the second layer such that the via structure is communicatively coupled to the second conductive element;
wherein: the second conductive element defines therein a recess, and the narrow end width of the via structure is contained within the recess, a width of the first conductive element being wider than the recess and the narrow end width contained within the recess;
wherein a combined width of the first conductive element and the intermediate layer is configured to be greater that a wide portion of the second conductive element.

14. The method of claim 13, wherein defining the via structure comprises:
coating the first layer with resist, resist stack, or hardmask;
defining a via pillar from the resist, resist stack, or hardmask; and
etching exposed portions of the first layer not masked by the via pillar.

15. The method of claim 13, wherein defining the via structure includes defining the via structure using an anisotropic etching technique.

16. The method of claim 13, further comprising polishing the intermediate layer such that the second end of the via structure protrudes from a surface of the intermediate layer.

17. The method of claim 13, further comprising depositing an interface material on the via structure and the first conductive element.

18. The method of claim 13, wherein depositing the first layer includes depositing a metal selected from a group consisting of copper, tungsten, cobalt, rhodium, platinum, or combinations thereof.

19. The method of claim 13, wherein depositing the second layer includes depositing a metal selected from a group consisting of copper, tungsten, cobalt, rhodium, platinum, or combinations thereof.

20. The method of claim 13, wherein depositing the intermediate layer comprises depositing a dielectric material.
